(19) United States
(12) Patent Application Publication
(10) Pub. No.: US 2025/0294840 A1
(43) Pub. Date: Sep. 18, 2025

(54) TWO-DIMENSIONAL DIRAC MATERIAL-BASED CHARGE SUPER INJECTION MEMORY AND PREPARATION THEREOF

(71) Applicant: Fudan University, Shanghai (CN)

(72) Inventors: Chunsen LIU, Shanghai (CN); Chong WANG, Shanghai (CN); Peng ZHOU, Shanghai (CN)

(21) Appl. No.: 19/224,647

(22) Filed: May 30, 2025

(30) Foreign Application Priority Data
Mar. 10, 2025 (CN) 202510273997.6

(51) Int. Cl. H10D 62/83; G11C 11/419; H10B 10/00

(52) U.S. Cl. CPC H10D 62/83; G11C 11/419; H10B 10/12

(57) ABSTRACT

A two-dimensional (2D) Dirac material-based charge super injection memory, which includes a substrate, a gate electrode provided on the substrate, a blocking layer covering the substrate electrode and the gate electrode, a charge storage layer provided on the blocking layer, a tunneling layer provided on the charge storage layer, a channel provided on the tunneling layer, and a source electrode and a drain electrode both provided on the channel. The channel material is a 2D Dirac material with a tapered band structure, and the electron affinity of the channel material is greater than that of the tunneling layer material. The electron affinity of the charge storage layer material exceeds those of both the tunneling layer material and the blocking layer material, and the bandgap of the charge storage layer material is smaller than those of the tunneling layer material and the blocking layer material.

### CROSS-REFERENCE TO RELATED APPLICATIONS

This application claims the benefit of priority from Chinese Patent Application No. 202510273997.6, filed on Mar. 10, 2025. The content of the aforementioned application, including any intervening amendments thereto, is incorporated herein by reference in its entirety.

### TECHNICAL FIELD

This application relates to semiconductor memories, and more specifically to a two-dimensional Dirac material-based charge super injection memory and a preparation thereof.

### BACKGROUND

Currently, global mainstream memory technologies are categorized into volatile memory and non-volatile memory based on their ability to retain stored data after power off. Static random-access memory (SRAM) is a widely used volatile memory, with its greatest advantage being high-speed data access and processing. The fastest SRAM currently available can complete data programming within 1 nanosecond. However, SRAM suffers from a significant drawback, i.e., extremely short data retention time, typically far less than 1 s, meaning stored data is rapidly lost after power interruption. Consequently, SRAM requires frequent refresh operations to maintain data stability, which increases system power consumption and limits its applicability in certain scenarios. Due to these limitations, SRAM is primarily used as small-capacity high-speed cache in computers, with restricted application scope. In contrast, non-volatile memory can retain data long-term after power off. Silicon-based flash memory, as a representative non-volatile memory, offers extended data retention (typically up to 10 years) but suffers from slower programming speeds, usually on the order of microseconds. This speed bottleneck makes traditional flash memory unsuitable for high-speed storage requirements, so that it is primarily applied to low-speed storage applications such as embedded systems and mobile device storage.

Thus, volatile and non-volatile memories each possess unique advantages and limitations. Volatile memory achieves high-speed programming but has extremely short data retention, leading to immediate data loss upon power interruption. While non-volatile memory maintains stored data after power off, granting it clear advantages in long-term data storage and backup. However, the programming speed of the non-volatile memory is relatively slow, which hinders its ability to meet high-speed data access demands, particularly showing significant disadvantages in high-performance applications requiring frequent read/write operations.

### SUMMARY

Objectives of the present disclosure are to provide a two-dimensional Dirac material-based charge super injection memory and a preparation thereof, which significantly enhances data retention capability while maintaining programming speeds at the hundreds of picosecond level.

Technical solutions of the present disclosure are described below.

In the first aspect, this application provides a two-dimensional (2D) Dirac material-based charge super injection memory, comprising:
a substrate;
a gate electrode;
a blocking layer;
a charge storage layer;
a tunneling layer;
a channel;
a source electrode; and
a drain electrode;
wherein the gate electrode is provided on the substrate; the blocking layer is configured to cover the substrate and the gate electrode; the charge storage layer is provided on the blocking layer; the tunneling layer is provided on the charge storage layer; the channel is provided on the tunneling layer; and the source electrode and the drain electrode are provided on the channel; and
a channel material is a 2D Dirac material with a tapered band structure; and an electron affinity of the channel material is greater than that of a tunneling layer material, an electron affinity of a charge storage layer material is greater than those of a tunneling layer material and a blocking layer material, and a bandgap of the charge storage layer material is smaller than those of the tunneling layer and blocking layer, so that the tunneling layer, the charge storage layer, and the blocking layer collectively form a potential well, thereby ensuring long-term retention of charges injected from the channel into the charge storage layer.

A 2D Dirac material is employed as the channel material. Carriers (electrons/holes) in the 2D Dirac material exhibit ultra-low effective mass, long mean free path, and significantly reduced scattering. Under applied voltage conditions that preserve the device integrity, the lateral electric field distribution within the two-dimensional Dirac material channel remains highly uniform. This enables carriers to undergo continuous acceleration throughout the channel, progressively gaining energy from the electric field, thereby achieving super charge injection into the storage layer.

In some embodiments, a substrate material is selected from the group consisting of rigid Si, SiO₂, Al₂O₃ and HfO₂; a gate electrode material is selected from the group consisting of Cr, Pt, Au, Ti, Pd and a combination thereof; the blocking layer material is selected from the group consisting of SiO₂, Al₂O₃, HfO₂, Si₃N₄, ZrO₂ and hBN; the charge storage layer material is selected from the group consisting of HfOₓ, Au, Pt and graphene; the tunneling layer material is selected from the group consisting of SiO₂, Al₂O₃, HfO₂ and hBN; the channel material is selected from the group consisting of graphene, silicene and germanene, with a thickness less than 10 nm; and a source electrode material and a drain electrode material are each selected from the group consisting of Cr, Pt, Au, Ti, Pd, Bi and Sb and a combination thereof.

The present disclosure also conducts simulation on the memory provided herein. Specifically, a technology computer-aided design (TCAD) software is used to perform simulation analysis of the memory device. The drift-diffusion approximation is applied to simulate the carrier transport process in the two-dimensional Dirac material channel. The high-field velocity saturation model is employed to simulate carrier velocity saturation under a high electric field. The Shockley-Read-Hall (SRH) recombination model and Auger recombination model are utilized to describe carrier exchange processes between the conduction and valence bands. Using source electrode voltage, drain electrode voltage, and gate electrode voltage as boundary conditions, the Poisson equation, carrier transport equations, and carrier continuity equations are numerically solved to obtain the distribution of physical quantities within the memory.

In a second aspect, this application provides a method for preparing the aforementioned memory, comprising:
(1) defining a position of the gate electrode on the substrate using lithography, followed by deposition via physical vapor deposition and exfoliation to form the gate electrode;
(2) depositing or transferring the blocking layer, charge storage layer, and tunneling layer sequentially using atomic layer deposition or dry transfer techniques;
(3) transfer the channel material onto the tunneling layer using a transfer technique, or growing the channel material on the tunneling layer via chemical vapor deposition; and perform thermal annealing on the partially fabricated device to enhance structural stability; and
(4) fabricating the source electrode and the drain electrode using the same method as for the gate electrode.

In a third aspect, this application provides a method for operating the aforementioned memory, comprising:
(1) programming the memory to a “1” state as the following steps:
maintaining the source electrode at ground potential, and applying a positive-polarity pulse to the gate electrode and the drain electrode, such that electrons accelerate from the source electrode to the drain electrode in the channel to gain energy, and then are injected into the charge storage layer, or
maintaining the gate electrode and the source electrode at ground potential, and applying a negative-polarity pulse to the drain electrode, such that electron accelerate from the drain electrode to the source electrode in the channel to gain energy, and then are injected into the charge storage layer; and
(2) programming the memory to a “O” state as the following steps:
maintain the source electrode at ground potential, and applying a negative-polarity pulse to the gate electrode and the drain electrode, such that holes accelerate from the source electrode to the drain electrode in the channel to gain energy, and then are injected into the charge storage layer; and
maintaining the gate electrode and the source electrode at ground potential, and applying a positive-polarity pulse to the drain electrode, such that holes accelerate from the drain electrode to the source electrode in the channel to gain energy, and then are inject into the charge storage layer.

The memory provided herein achieves programming speeds as fast as hundreds of picoseconds while offering data retention capability exceeding 10 years, thereby fully integrating the advantages of both conventional volatile and non-volatile memories.

### BRIEF DESCRIPTION OF THE DRAWINGS

FIG. 1 is a schematic structural diagram of a two-dimensional Dirac material-based charge super injection memory according to an embodiment of the present disclosure;

FIG. 2 schematically shows an energy band structure of the memory along a direction perpendicular to a channel of the memory according to an embodiment of the present disclosure;

FIG. 3 is a curve showing lateral electric field distribution in the 2D Dirac material channel of the memory under an applied voltage according to an embodiment of the present disclosure;

FIG. 4 is a curve showing changes of the maximum lateral electric field intensity in the channel versus channel thickness variation obtained by a technology computer-aided design (TCAD) software simulation according to an embodiment of the present disclosure; and

FIG. 5 schematically shows a preparation process of the memory according to an embodiment of the present disclosure.

In the drawings:
1, channel; 2, tunneling layer; 3, charge storage layer; 4, blocking layer; 5, substrate; 6, source electrode; 7, drain electrode; and 8, gate electrode.

### DETAILED DESCRIPTION OF EMBODIMENTS

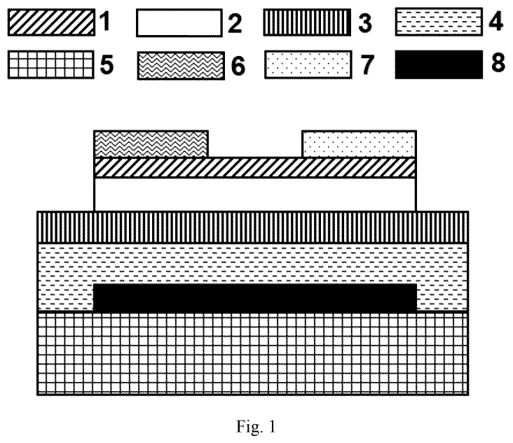

As shown in FIG. 1, this application provides a two-dimensional (2D) Dirac material-based charge super injection memory, which includes a substrate, a gate electrode provided on the substrate, a blocking layer covering the substrate electrode and the gate electrode, a charge storage layer provided on the blocking layer, a tunneling layer provided on the charge storage layer, a channel provided on the tunneling layer, and a source electrode and a drain electrode both provided on the channel.

A substrate material is preferably selected from the group consisting of rigid Si, SiO₂, Al₂O₃ and HfO₂.

A gate electrode material is preferably selected from the group consisting of Cr, Pt, Au, Ti, Pd and a combination thereof.

The blocking layer material is preferably selected from the group consisting of SiO₂, Al₂O₃, HfO₂, Si₃N₄, ZrO₂ and hBN.

The charge storage layer material is preferably selected from the group consisting of HfOₓ, Au, Pt and graphene.

The tunneling layer material is preferably selected from the group consisting of SiO₂, Al₂O₃, HfO₂ and hBN.

The channel material is preferably selected from the group consisting of graphene, silicene and germanene.

A source electrode material and a drain electrode material are each preferably selected from the group consisting of Cr, Pt, Au, Ti, Pd, Bi and Sb and a combination thereof.

In an embodiment, the gate electrode material is Pt, the blocking layer material is Al₂O₃, the charge storage layer material is HfO₂, the tunneling layer material is hBN, the channel material is graphene, and the source electrode material and the drain electrode material is Au.

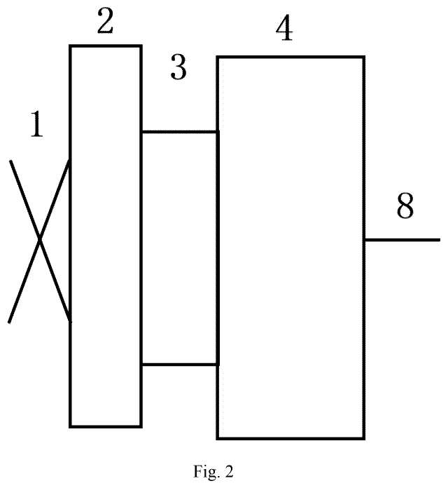

As shown in FIG. 2, the channel material of the memory should be a two-dimensional Dirac material with a tapered band structure, and the electron affinity of the channel material must be greater than that of the tunneling layer material. The electron affinity of the charge storage layer material must exceed those of both the tunneling layer material and the blocking layer material, and the bandgap of the charge storage layer material is preferably smaller than those of the tunneling layer material and the blocking layer material. Only when the above band structure design principles are satisfied can the tunneling layer, the charge storage layer, and the blocking layer form a potential well, ensuring that charges injected from the channel into the charge storage layer remain trapped for extended periods.

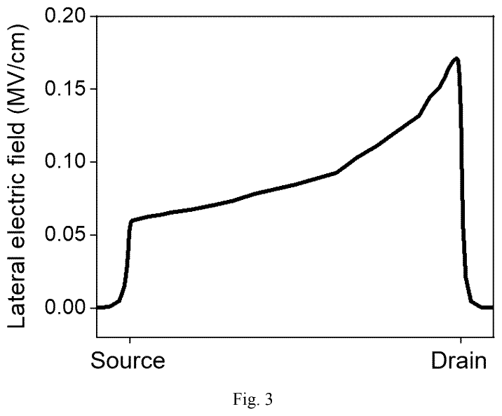

A 2D Dirac material with a tapered band structure is employed as the channel material. Carriers (electrons/holes) in the 2D Dirac material exhibit ultra-low effective mass, long mean free path, and significantly reduced scattering. As shown in FIG. 3, compared to a semiconductor material channel, under the same applied voltage conditions, the lateral electric field distribution in the 2D Dirac material channel is more uniform. Carriers can undergo relatively uniform acceleration throughout the channel, continuously gaining energy from the electric field, thereby achieving super charge injection.

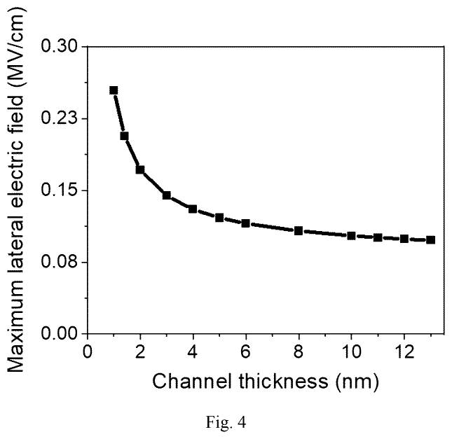

The present disclosure also conducts simulation on the memory provided herein. Specifically, a technology computer-aided design (TCAD) software is used to perform simulation analysis of the memory device. The drift-diffusion approximation is applied to simulate the carrier transport process in the two-dimensional Dirac material channel. The high-field velocity saturation model is employed to simulate carrier velocity saturation under a high electric field. The Shockley-Read-Hall (SRH) recombination model and Auger recombination model are utilized to describe carrier exchange processes between the conduction and valence bands. Using source electrode voltage, drain electrode voltage, and gate electrode voltage as boundary conditions, the Poisson equation, carrier transport equations, and carrier continuity equations are numerically solved to obtain the distribution of physical quantities within the memory. FIG. 4 illustrates the relationship between the maximum lateral electric field intensity within the 2D Dirac material channel and the channel thickness under a fixed applied voltage, derived from the aforementioned simulation. The results demonstrate that reducing the channel thickness leads to a progressive increase in the maximum lateral electric field. This enhancement directly elevates the energy acquired by accelerating carriers within the channel, thereby amplifying charge injection efficiency. To optimize the performance of the memory, the 2D Dirac material channel should be fabricated with a thickness below 10 nm.

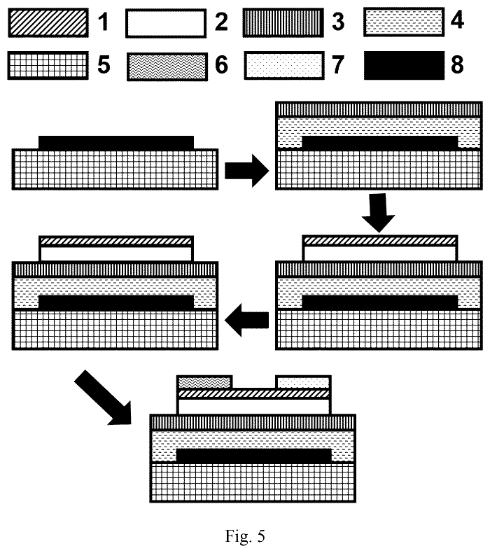

The present disclosure also provides a method for preparing the aforementioned memory, as shown in FIG. 5, which includes the following steps.
(1) The position of the metal gate electrode on the substrate is defined using lithography or electron-beam lithography. The metal gate material (e.g., Au, Pt, Cr, Ti, or stacked metal layers) is deposited via physical vapor deposition (PVD) followed by exfoliation to form the gate electrode.
(2) Al₂O₃ (blocking layer) and HfO₂ (charge storage layer) are deposited sequentially using atomic layer deposition (ALD) or chemical vapor deposition (CVD).
(3) The hBN (tunneling layer) is transferred onto the gate electrode, and the graphene (channel) is transferred onto the hBN.
(4) Thermal annealing is performed on the partially fabricated device to enhance structural stability.
(5) The source electrode and the drain electrode are fabricated using the same method as described in step (1).

The present disclosure further provides a method for operating the aforementioned memory.

For an electron injection operation (programming the memory to a “1” state), there are two modes for operation: (1) the source electrode is maintained at ground potential, and a positive-polarity pulse is applied to the gate electrode and the drain electrode, such that electrons accelerate from the source electrode to the drain electrode in the channel to gain energy, and then are injected into the charge storage layer; (2) the gate electrode and the source electrode are maintained at ground potential, and a negative-polarity pulse is applied to the drain electrode, such that electron accelerate from the drain electrode to the source electrode in the channel to gain energy, and then are injected into the charge storage layer.

For a hole injection (programming the memory to a “0” state), there are two modes for operation: (1) the source electrode is maintained at ground potential, and a negative-polarity pulse is applied to the gate electrode and the drain electrode, such that holes accelerate from the source electrode to the drain electrode in the channel to gain energy, and then are injected into the charge storage layer; and (2) the gate electrode and the source electrode are maintained at ground potential, and a positive polarity pulse is applied to the drain electrode, such that holes accelerate from the drain electrode to the source electrode in the channel to gain energy, and then are inject into the charge storage layer.

What is claimed is:

1. A two-dimensional (2D) Dirac material-based charge super injection memory, comprising:
a substrate;
a gate electrode;
a blocking layer;
a charge storage layer;
a tunneling layer;
a channel;
a source electrode; and
a drain electrode;
wherein the gate electrode is provided on the substrate; the blocking layer is configured to cover the substrate and the gate electrode; the charge storage layer is provided on the blocking layer; the tunneling layer is provided on the charge storage layer; the channel is provided on the tunneling layer; and the source electrode and the drain electrode are provided on the channel; and
a channel material is a 2D Dirac material with a tapered band structure; and an electron affinity of the channel material is greater than that of a tunneling layer material, an electron affinity of a charge storage layer material is greater than those of a tunneling layer material and a blocking layer material, and a bandgap of the charge storage layer material is smaller than those of the tunneling layer and blocking layer, so that the tunneling layer, the charge storage layer, and the blocking layer collectively form a potential well, thereby ensuring long-term retention of charges injected from the channel into the charge storage layer.

2. The 2D Dirac material-based charge super injection memory of claim 1, wherein under an applied voltage condition that preserve the device structure, a lateral electric field is uniformly distributed in the channel, enabling continuous acceleration of carriers throughout the channel while progressively acquiring energy from the electric field to achieve charge super injection.

3. The 2D Dirac material-based charge super injection memory of claim 1, wherein a substrate material is selected from the group consisting of rigid Si, SiO₂, Al₂O₃ and HfO₂;
a gate electrode material is selected from the group consisting of Cr, Pt, Au, Ti, Pd and a combination thereof;
the blocking layer material is selected from the group consisting of SiO₂, Al₂O₃, HfO₂, Si₃N₄, ZrO₂ and hBN;
the charge storage layer material is selected from the group consisting of HfOₓ, Au, Pt and graphene;
the tunneling layer material is selected from the group consisting of SiO₂, Al₂O₃, HfO₂ and hBN;
the channel material is selected from the group consisting of graphene, silicene and germanene, with a thickness less than 10 nm; and
a source electrode material and a drain electrode material are each selected from the group consisting of Cr, Pt, Au, Ti, Pd, Bi, Sb and a combination thereof.

4. A method for preparing the 2D Dirac material-based charge super injection memory of claim 1, comprising:
(1) defining a position of the gate electrode on the substrate using lithography, followed by deposition via physical vapor deposition and exfoliation to form the gate electrode;
(2) depositing or transferring the blocking layer, charge storage layer, and tunneling layer sequentially using atomic layer deposition or dry transfer techniques;
(3) transfer the channel material onto the tunneling layer using a transfer technique, or growing the channel material on the tunneling layer via chemical vapor deposition; and perform thermal annealing on the partially fabricated device to enhance structural stability; and
(4) fabricating the source electrode and the drain electrode using the same method as for the gate electrode.

5. A method for operating the memory of claim 1, comprising:
(1) programming the memory to a “1” state through the following steps: maintaining the source electrode at ground potential, and applying a positive-polarity pulse to the gate electrode and the drain electrode, such that electrons accelerate from the source electrode to the drain electrode in the channel to gain energy, and then are injected into the charge storage layer; or
maintaining the gate electrode and the source electrode at ground potential, and applying a negative-polarity pulse to the drain electrode, such that electron accelerate from the drain electrode to the source electrode in the channel to gain energy, and then are injected into the charge storage layer; and
(2) programming the memory to a “0” state through the following steps:
maintain the source electrode at ground potential, and applying a negative-polarity pulse to the gate electrode and the drain electrode, such that holes accelerate from the source electrode to the drain electrode in the channel to gain energy, and then are injected into the charge storage layer; or
maintaining the gate electrode and the source electrode at ground potential, and applying a positive-polarity pulse to the drain electrode, such that holes accelerate from the drain electrode to the source electrode in the channel to gain energy, and then are inject into the charge storage layer.
